(19) United States
(12) Patent Application Publication
(10) Pub. No.: US 2019/0258161 A1
(43) Pub. Date: Aug. 22, 2019

(54) RADIATION-SENSITIVE COMPOSITION AND PATTERN-FORMING METHOD

(71) Applicant: JSR CORPORATION, Tokyo (JP)

(72) Inventor: Kazunori SAKAI, Tokyo (JP)

(73) Assignee: JSR CORPORATION, Tokyo (JP)

(21) Appl. No.: 16/282,698

(22) Filed: Feb. 22, 2019

Related U.S. Application Data
(60) Provisional application No. 62/633,836, filed on Feb. 22, 2018.

(51) Int. Cl. G03F 7/004; G03F 7/16; G03F 7/20; G03F 7/32

(52) U.S. Cl. CPC G03F 7/0042; G03F 7/0045; G03F 7/325; G03F 7/2037; G03F 7/162

(57) ABSTRACT

A radiation-sensitive composition contains: a compound which includes a metal atom, a ligand derived from an organic acid and ligand derived from a base; and an organic solvent. The base is other than a triethylamine. Also, a radiation-sensitive composition contains: a compound obtained by mixing a metal-containing compound, an organic acid and a base; and an organic solvent. The base is other than a triethylamine.

### CROSS-REFERENCE TO RELATED APPLICATIONS

The present application claims priority to U.S. Provisional Patent Application Ser. No. 62/633,836 filed on Feb. 22, 2018, the contents of which are incorporated herein by reference in their entirety.

### BACKGROUND OF THE INVENTION

### Field of Invention

The present invention relates to a radiation-sensitive composition and a pattern-forming method.

### Discussion of the Background

Conventionally, in manufacturing processes of semiconductor devices such as IC and LSI, microfabrication by lithography using a radiation-sensitive composition has been carried out. In recent years, integration in integrated circuits has been accompanied by demands for ultrafine pattern formation on a sub-micron scale and a quarter-micron scale. With such demands, shorter exposure wavelengths, e.g., from g-line to i-line, a KrF excimer laser beam, and further an ArF excimer laser beam have come to be employed. In addition, more recently, lithography techniques using extreme ultraviolet rays (EUV), electron beams, and the like in addition to the excimer laser beams have been developed (see Japanese Unexamined Patent Application, Publication No. 2006-171440, Japanese Unexamined Patent Application, Publication No. 2011-16746 and Japanese Unexamined Patent Application, Publication No. 2010-204634).

The lithography techniques carried out through use of EUV or electron beams have been anticipated as next-generation pattern formation techniques that enable a pattern formation on an ultrafine scale of no greater than 32 nm. However, an exposure carried out by using EUV is disadvantageous in low throughput due to insufficient power of an exposure light source, leading to problems which should be solved. In order to solve such problems, devices for improving the output of the light source have been investigated, whereas radiation-sensitive compositions are required to have increased sensitivity. To meet the requirements, use of a metal-containing substance as a component of the radiation-sensitive composition has been investigated. Metal-containing substances generate secondary electrons through absorbing EUV light and the like, and an action of the secondary electrons promotes generation of an acid from an acid generating agent or the like, thereby enabling the sensitivity to be improved, and thus formation of a pattern with high resolution is believed to be enabled.

### SUMMARY OF THE INVENTION

According to an aspect of the present invention, a radiation-sensitive composition contains: a compound including a metal atom, a ligand derived from an organic acid, and a ligand derived from a base; and an organic solvent. The base is other than a triethylamine.

According to another aspect of the present invention, a radiation-sensitive composition contains: a compound obtained by blending a metal-containing compound, an organic acid and a base; and an organic solvent. The base is other than a triethylamine.

According to further aspect of the present invention, a pattern-forming method includes applying the radiation-sensitive composition directly or indirectly on an upper face side of a substrate to provide a film. The film provided by the applying of the radiation-sensitive composition is exposed. The film exposed is developed.

### DESCRIPTION OF EMBODIMENTS

According to an embodiment of the invention, a radiation-sensitive composition comprises: a compound (hereinafter, may be also referred to as “(A) compound” or “compound (A)”) comprising a metal atom (hereinafter, may be also referred to as “(a) metal atom” or “metal atom (a)”), a ligand (hereinafter, may be also referred to as “(b) ligand” or “ligand (b)”) derived from an organic acid (hereinafter, may be also referred to as “(y) organic acid” or “organic acid (y)”), and a ligand (hereinafter, may be also referred to as “(c) ligand” or “ligand (c)”) derived from a base (hereinafter, may be also referred to as “(z) base” or “base (z)”); and an organic solvent (hereinafter, may be also referred to as “(B) organic solvent” or “organic solvent (B)”), wherein the base (z) is other than a triethylamine.

According to another embodiment of the invention, a radiation-sensitive composition comprises: a compound obtained by blending a metal-containing compound (hereinafter, may be also referred to as “(x) metal-containing compound” or “metal-containing compound (x)”), an organic acid (organic acid (y)) and a base (base (z)); and an organic solvent (organic solvent (B)), wherein the base (z) is other than a triethylamine.

According to yet another embodiment of the invention, a pattern-forming method comprises: applying the aforementioned radiation-sensitive composition directly or indirectly on an upper face side of a substrate; exposing a film provided by the applying; and developing the film exposed.

According to the radiation-sensitive compositions and the pattern-forming method of the embodiments of the present invention, formation of a pattern is enabled with superior sensitivity and favorable resolution maintained. Therefore, these can be suitably used for formation of fine resist patterns in lithography processes of various types of electronic devices such as semiconductor devices and liquid crystal devices in which further progress of microfabrication is expected in the future.

### Radiation-Sensitive Composition

The radiation-sensitive compositions of embodiments of the present invention involve a radiation-sensitive composition (hereinafter, may be also referred to as “radiation-sensitive composition (I)”) containing: the compound (A) which includes the metal atom (a), the ligand (b) and the ligand (c); and the organic solvent (B), and a radiation-sensitive composition (hereinafter, may be also referred to as “radiation-sensitive composition (II)”) containing: a compound obtained by blending the metal-containing compound (x), the organic acid (y) and the base (z); and the organic solvent (B).

The radiation-sensitive compositions are superior in sensitivity, with favorable resolution being maintained, due to having the aforementioned constitutions. Although not necessarily clarified, the reason for achieving the effects described above due to the radiation-sensitive composition having the aforementioned constitution is inferred as in the following, for example. Specifically, in the radiation-sensitive composition, the compound (A) includes the metal atom (a), the ligand (b) and the ligand (c), in which the ligand (c) is derived from the base other than a triethylamine. In connection with the sensitivity of the radiation-sensitive composition in which a metal-containing compound is employed, the amount of generation of secondary electrons from the metal atom (a) upon an exposure is considered to vary depending on not only the type of the metal atom (a) but also the structure, etc., of the ligand (b) and/or the ligand (c). The present invention is based on a finding that the sensitivity is improved by using a substance other than a conventional triethylamine as the base (z) that gives the ligand (c). In the following, the radiation-sensitive composition (I) will be described.

### Radiation-Sensitive Composition (I)

The radiation-sensitive composition (I) contains: the compound (A) that includes the metal atom (a), the ligand (b) and the ligand (c); and the organic solvent (B). The radiation-sensitive composition (I) may also contain a radiation-sensitive acid generating agent (hereinafter, may be also referred to as “(C) acid generating agent” or “acid generating agent (C)”) as a favorable component, and within a range not leading to impairment of the effects of the present invention, may also contain other optional component(s). Each component will be described below.

### (A) Compound

The compound (A) includes the metal atom (a), the ligand (b) and the ligand (c). The compound (A) may include other component(s) in addition to the metal atom (a), the ligand (b) and the ligand (c), within a range not leading to impairment of the effects of the present invention. The compound (A) is capable of generating secondary electrons through absorbing radioactive rays due to including the metal atom (a), the ligand (b) and the ligand (c), and thus the action of the secondary electrons facilitates generation of an acid caused by degradation of the acid generating agent (C) or the like. As a result, the radiation-sensitive composition (I) enables a pattern with high resolution to be formed by changing the solubility of the compound (A) in a developer solution.

(a) Metal Atom

The metal atom (a) included in the compound (A) is exemplified by metal atoms from groups 3 to 16, and the like. The compound (A) may include one, or two or more types of the metal atom (a).

Examples of the metal atoms from group 3 include a scandium atom, an yttrium atom, a lanthanum atom, a cerium atom and the like.

Examples of the metal atoms from group 4 include a titanium atom, a zirconium atom, a hafnium atom and the like.

Examples of the metal atoms from group 5 include a vanadium atom, a niobium atom, a tantalum atom and the like.

Examples of the metal atoms from group 6 include a chromium atom, a molybdenum atom, a tungsten atom and the like.

Examples of the metal atoms from group 7 include a manganese atom, a rhenium atom and the like.

Examples of the metal atoms from group 8 include an iron atom, a ruthenium atom, an osmium atom and the like.

Examples of the metal atoms from group 9 include a cobalt atom, a rhodium atom, an iridium atom and the like.

Examples of the metal atoms from group 10 include a nickel atom, a palladium atom, a platinum atom and the like.

Examples of the metal atoms from group 11 include a copper atom, a silver atom, a gold atom and the like.

Examples of the metal atoms from group 12 include a zinc atom, a cadmium atom, a mercury atom and the like.

Examples of the metal atoms from group 13 include an aluminum atom, a gallium atom, an indium atom and the like.

Examples of the metal atoms from group 14 include a germanium atom, a tin atom, a lead atom and the like.

Examples of the metal atoms from group 15 include an antimony atom, a bismuth atom and the like.

Examples of the metal atoms from group 16 include a tellurium atom and the like.

The metal atom (a) is preferably the metal atom from groups 3 to 15, more preferably the metal atom from group 4, group 5, group 6, group 8, group 9, group 10, group 11, group 12, group 13 and group 14, still more preferably a titanium atom, a zirconium atom, a hafnium atom, a tantalum atom, a tungsten atom, an iron atom, a cobalt atom, a nickel atom, a copper atom, a zinc atom, an indium atom, a tin atom or a combination thereof, and particularly preferably a zirconium atom, a hafnium atom, a cobalt atom, a nickel atom, a zinc atom or an indium atom.

The lower limit of the percentage content of the metal atom (a) in the compound (A) is preferably 1% by mass, more preferably 5% by mass, and still more preferably 10% by mass. The upper limit of the content is preferably 99% by mass, more preferably 95% by mass, and still more preferably 90% by mass. When the percentage content of the metal atom (a) in the compound (A) falls within the above range, a more improvement of the sensitivity of the radiation-sensitive composition is enabled.

(b) Ligand

The ligand (b) is derived from the organic acid (y). The ligand (b) is exemplified by, the organic acid (y), an ion derived from the organic acid (y), and the like. The ligand (b) is believed to bond to the metal atom (a) in the compound (A) via a coordinate bond or the like.

The “organic acid” as referred to herein means an acidic organic compound, and the “organic compound” as referred to means a compound having at least one carbon atom.

The lower limit of pKa of the organic acid (y) is preferably 0, more preferably 1, still more preferably 1.5, and particularly preferably 3. Meanwhile, the upper limit of the pKa is preferably 7, more preferably 6, still more preferably 5.5, and particularly preferably 5. When the pKa of the organic acid (y) falls within the above range, it is possible to adjust the interaction with the metal atom to be moderately weak, whereby a more improvement of the sensitivity of the radiation-sensitive composition (I) is consequently enabled. As used herein, in the case of the organic acid (y) being a polyvalent acid, the pKa of the organic acid (y) as referred to means a primary acid dissociation constant, i.e., a common logarithmic value of a reciprocal of a dissociation constant for dissociation of the first proton.

The organic acid (y) may be either a low molecular weight compound or a high molecular weight compound, and a low molecular weight compound is preferred in light of adjusting the interaction with the metal atom to be more appropriately weak. The “low molecular weight compound” as referred to means a compound having a molecular weight of no greater than 1,500, whereby the “high molecular weight compound” as referred to means a compound having a molecular weight of greater than 1,500. The lower limit of the molecular weight of the organic acid (y) is preferably 50, and more preferably 80. Meanwhile, the upper limit of the molecular weight is preferably 1,000, more preferably 500, further more preferably 400, and particularly preferably 300. When the molecular weight of the organic acid (y) falls within the above range, it is possible to adjust the solubility or dispersibility of the compound (A) to be more appropriate, and consequently a more improvement of the sensitivity of the radiation-sensitive composition (I) is enabled.

The organic acid (y) is exemplified by a carboxylic acid, a sulfonic acid, a sulfinic acid, an organic phosphinic acid, an organic phosphonic acid, a phenol, an enol, a thiol, an acid imide, an oxime, a sulfonamide, and the like.

Examples of the carboxylic acid include:

monocarboxylic acids such as formic acid, acetic acid, propionic acid, butanoic acid, pentanoic acid, hexanoic acid, heptanoic acid, octanoic acid, nonanoic acid, decanoic acid, 2-ethylhexanoic acid, oleic acid, acrylic acid, methacrylic acid, trans-2,3-dimethylacrylic acid, stearic acid, linoleic acid, linolenic acid, arachidonic acid, salicylic acid, benzoic acid, m-toluic acid, p-aminobenzoic acid, monochloroacetic acid, dichloroacetic acid, trichloroacetic acid, trifluoroacetic acid, pentafluoropropionic acid, 3-fluorobenzoic acid, 3-iodobenzoic acid, gallic acid and shikimic acid;

dicarboxylic acids such as oxalic acid, malonic acid, maleic acid, methylmalonic acid, fumaric acid, adipic acid, sebacic acid, phthalic acid and tartaric acid;

carboxylic acids having no less than 3 carboxy groups such as citric acid; and the like.

Examples of the sulfonic acid include benzenesulfonic acid, p-toluenesulfonic acid, and the like.

Examples of the sulfinic acid include benzenesulfinic acid, p-toluenesulfinic acid, and the like.

Examples of the organic phosphinic acid include diethylphosphinic acid, methylphenylphosphinic acid, diphenylphosphinic acid, and the like.

Examples of the organic phosphoric acid include methylphosphonic acid, ethyiphosphonic acid, t-butylphosphonic acid, cyclohexylphosphonic acid, phenylphosphonic acid, and the like.

Examples of the phenol include: monovalent phenols such as phenol, cresol, 2,6-xylenol and naphthol;

divalent phenols such as catechol, resorcinol, hydroquinone and 1,2-naphthalenediol;

phenols having a valency of no less than 3 such as pyrogallol and 2,3,6-naphthalenetriol; and the like.

Examples of the enol include 2-hydroxy-3-methyl-2-butene, 3-hydroxy-4-methyl-3-hexene, and the like.

Examples of the thiol include mercaptoethanol, mercaptopropanol, and the like.

Examples of the acid imide include:

carboxylic imides such as maleimide and succinimide;

sulfonic imides such as a di(trifluoromethanesulfonic acid) imide and di(pentafluoroethanesulfonic acid) imide; and the like.

Examples of the oxime include:

aldoximes such as benzaldoxime and salicylaldoxime;

ketoximes such as diethylketoxime, methylethylketoxime and cyclohexanoneoxime; and the like.

Examples of the sulfonamide include methylsulfonamide, ethylsulfonamide, benzenesulfonamide, toluenesulfonamide, and the like.

In light of a more improvement of the sensitivity of the radiation-sensitive composition (I), the organic acid (y) is preferably the carboxylic acid, more preferably the monocarboxylic acid, and still more preferably m-toluic acid, 3-fluorobenzoic acid, 3-iodobenzoic acid or methacrylic acid.

The upper limit of the boiling point of the organic acid (y) is preferably 400° C., more preferably 350° C., and still more preferably 300° C. The lower limit of the boiling point is preferably 80° C., more preferably 90° C., and still more preferably 100° C. When the boiling point of the organic acid (y) falls within the above range, a more improvement of the sensitivity of the radiation-sensitive composition (I) is enabled.

The lower limit of the percentage content of the ligand (b) in the compound (A) is preferably 1% by mass, more preferably 5% by mass, and still more preferably 10% by mass. Meanwhile, the upper limit of the percentage content is preferably 90% by mass, more preferably 70% by mass, and still more preferably 50% by mass. When the percentage content of the ligand (b) falls within the above range, it is possible to adjust the solubility or dispersibility of the compound (A) to be further appropriate, and consequently a more improvement of the sensitivity of the radiation-sensitive composition (I) is enabled. The compound (A) may include either only one type, or two or more types of the ligand (b).

(c) Ligand

The ligand (c) is derived from the base (z). The base (z) is other than a triethylamine. The ligand (c) is exemplified by the base (z), an ion derived from the base (z), and the like. The ligand (c) is believed to bond to the metal atom (a) in the compound (A) via a coordinate bond or the like.

The “base” as referred to herein means a basic substance, and may involve an Arrhenius base, a Broensted base and a Lewis base.

The base (z) is exemplified by: an organic compound such as a nitrogen-containing compound that includes a nitrogen atom having an unshared electron pair, and a phosphorus-containing compound that includes a phosphorus atom having an unshared electron pair; and an inorganic compound such as a metal hydroxide salt and a metal carbonic acid salt. Of these, the organic compound is preferred, and the nitrogen-containing compound is more preferred.

The nitrogen-containing compound is exemplified by the amine compound represented by the following formula (1), and the like.

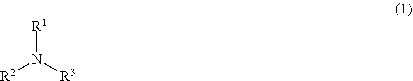

In the above formula (1), R¹, R² and R³ each independently represent a substituted or unsubstituted monovalent hydrocarbon group having 1 to 20 carbon atoms or a hydrogen atom, or two or more of R¹, R² and R³ taken together represent a ring structure having 3 to 20 ring atoms together with the nitrogen atom to which the two or more of R¹, R² and R³ bond. At least one of R¹, R² and R³ does not represent an ethyl group.

The monovalent hydrocarbon group having 1 to 20 carbon atoms which may be represented by R¹, R² or R³ is exemplified by a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and the like.

The “hydrocarbon group” involves a chain hydrocarbon group, an alicyclic hydrocarbon group and an aromatic hydrocarbon group. The “hydrocarbon group” may be either a saturated hydrocarbon group or an unsaturated hydrocarbon group. The “chain hydrocarbon group” as referred to herein means a hydrocarbon group not having a ring structure but being constituted only from a chain structure, and involves both a linear hydrocarbon group and a branched hydrocarbon group. The “alicyclic hydrocarbon group” as referred to herein means a hydrocarbon group having as a ring structure, not an aromatic ring structure but only an alicyclic structure, and involves both a monocyclic alicyclic hydrocarbon group and a polycyclic alicyclic hydrocarbon group. It is not necessary that the alicyclic hydrocarbon group is constituted from only the alicyclic structure, and a part thereof may also include a chain structure. The “aromatic hydrocarbon group” as referred to herein means a hydrocarbon group that includes an aromatic ring structure as the ring structure. It is not necessary that the aromatic hydrocarbon group is constituted from only the aromatic ring structure, and a part thereof may also include a chain structure and/or an alicyclic structure.

Examples of the monovalent chain hydrocarbon group having 1 to 20 carbon atoms include:

alkyl groups such as a methyl group, an ethyl group, a n-propyl group, an i-propyl group and a t-butyl group;

alkenyl groups such as an ethenyl group, a propenyl group and a butenyl group;

alkynyl groups such as an ethynyl group, a propynyl group and a butynyl group; and the like.

Examples of the monovalent alicyclic hydrocarbon group having 3 to 20 carbon atoms include:

monocyclic alicyclic saturated hydrocarbon groups such as a cyclopentyl group and a cyclohexyl group;

monocyclic alicyclic unsaturated hydrocarbon groups such as a cyclopentenyl group and a cyclohexenyl group;

polycyclic alicyclic saturated hydrocarbon groups such as a norbornyl group, an adamantyl group and a tricyclodecyl group;

polycyclic alicyclic unsaturated hydrocarbon groups such as a norbornenyl group and a tricyclodecenyl group; and the like.

Examples of the monovalent aromatic hydrocarbon group having 6 to 20 carbon atoms include:

aryl groups such as a phenyl group, a tolyl group, a xylyl group, a naphthyl group and an anthryl group;

aralkyl groups such as a benzyl group, a phenethyl group, a naphthylmethyl group and an anthrylmethyl group; and the like.

A substituent for the hydrocarbon group is exemplified by a hydroxy group, a halogen atom, a nitro group, a cyano group, an amino group, and the like.

Examples of the ring structure having 3 to 20 ring atoms which may be, taken together, represented by two or more of R¹, R² and R³ include:

azacycloalkane structures such as an azacyclopropane structure, an azacyclobutane structure, an azacyclopentane structure and an azacyclohexane structure;

azabicycloalkane structures such as an azabicyclo[2.2.2]octane structure and an azabicyclo[2.2.1]heptane structure;

nitrogen atom-containing aliphatic heterocyclic structures, e.g., azaoxacycloalkane structures such as an azaoxacyclohexane structure;

nitrogen atom-containing aromatic heterocyclic structures such as a pyrrole structure, an imidazole structure, a pyrazole structure, a pyridine structure, a pyrazine structure, a pyrimidine structure, a pyridazine structure, a quinoline structure, an isoquinoline structure, an acridine structure and a phenanthroline structure; and the like.

Examples of the amine compound include

monoamine compounds, e.g.,

tertiary amines such as diisopropylethylamine, tri-n-butylamine, tri-n-octylamine, N-methylpyrrolidine and N-ethylpiperidine;

secondary amines such as pyrrolidine, piperidine, di-n-butylamine, di-n-octylamine and morpholine; and

primary amines such as n-butylamine, n-octylamine, aniline and toluidine, as well as

diamine compounds such as hexamethylenediamine, N,N,N′,N′-tetramethylethylenediamine and 1,4-diazabicyclo[2.2.2]octane,

aromatic heterocyclic amine compounds such as pyridine, pyrrole, imidazole, pyrazine and triazine, and the like.

The lower limit of the pKb of the base (z) is preferably 3.1, more preferably 3.5, and still more preferably 4. The upper limit of the pKb is preferably 12, more preferably 10, and still more preferably 9. The “pKb” as referred to herein means a common logarithmic value of the reciprocal of the base dissociation constant (Kb) of a base at 25° C.

The lower limit of the boiling point of the base (z) is preferably 95° C., more preferably 110° C., still more preferably 125° C., and particularly preferably 140° C. The upper limit of the boiling point is preferably 400° C., more preferably 200° C., still more preferably 185° C., and particularly preferably 170° C.

The lower limit of the molecular weight of the base (z) is preferably 105, more preferably 115, still more preferably 125, and particularly preferably 135. The upper limit of the molecular weight is preferably 500, more preferably 400, still more preferably 300, and particularly preferably 200.

When at least any one of the pKb, boiling point and molecular weight of the base (z) falls within the range described above, a more improvement of the sensitivity of the radiation-sensitive composition (I) is enabled.

The lower limit of the percentage content of the ligand (c) in the compound (A) is preferably 1% by mass, more preferably 5% by mass, and still more preferably 10% by mass. Meanwhile, the upper limit of the percentage content is preferably 90% by mass, more preferably 70% by mass, and still more preferably 50% by mass. When the percentage content of the ligand (c) falls within the above range, a more improvement of the sensitivity of the radiation-sensitive composition (I) is enabled. The compound (A) may contain one, or two or more types of the ligand (c).

Other Components

The other component which may be included in the compound (A) is exemplified by other ligand except for the ligand (b) and the ligand (c), a metalloid atom such as a boron atom and a silicon atom; and the like.

The upper limit of the content of the other ligand or the metalloid atom in the compound (A) is preferably 20% by mass, and more preferably 5% by mass. The lower limit of the content is, for example, 0.1% by mass.

The lower limit of the content of the compound (A) in the radiation-sensitive composition (I) with respect to the total solid content of the radiation-sensitive composition (I) is preferably 50% by mass, more preferably 70% by mass, and still more preferably 90% by mass. The upper limit of the content is preferably 99% by mass, and more preferably 95% by mass. When the content of the compound (A) falls within the above range, a more improvement of the sensitivity of the radiation-sensitive composition (I) is enabled. The radiation-sensitive composition (I) may contain one, or two or more types of the compound (A). The “total solid content” as referred to herein means the sum of components other than the organic solvent (B) in the radiation-sensitive composition.

Synthesis Procedure of Compound (A)

The compound (A) may be synthesized by, for example: a procedure of carrying out a hydrolytic condensation reaction by using (x1) a metal-containing compound shown below and (y) an organic acid, and adding the base (z) to a resulting reaction product; or a procedure of carrying out a ligand substitution reaction by using (x2) a metal-containing compound described below and the organic acid (y), and adding the base (z) to a resulting reaction product. The “hydrolytic condensation reaction” as referred to herein means a reaction in which a hydrolyzable group included in the metal-containing compound (x1) is hydrolyzed to give —OH, and two —OHs thus obtained undergo dehydrative condensation to form —O—.

(x1) Metal-Containing Compound

The metal-containing compound (x1) may be: a metal compound (I) having a hydrolyzable group; a hydrolysis product of the metal compound (I) having a hydrolyzable group; a hydrolytic condensation product of the metal compound (I) having a hydrolyzable group; or a combination thereof. The metal compound (I) may be used either alone of one type, or in combination of two or more types thereof.

The hydrolyzable group is exemplified by a halogen atom, an alkoxy group, an acyloxy group, and the like.

Examples of the halogen atom include a fluorine atom, a chlorine atom, a bromine atom, an iodine, atom and the like.

Examples of the alkoxy group include a methoxy group, an ethoxy group, a n-propoxy group, an i-propoxy group, a butoxy group, and the like.

Examples of the acyloxy group include an acetoxy group, a propionyloxy group, a n-butyryloxy group, an i-butyryloxy group, a t-butyryloxy group, a t-amylyloxy group, a n-hexanecarbonyloxy group, a n-octanecarbonyloxy group and the like.

As the hydrolyzable group, an alkoxy group and an acyloxy group are preferred, and an isopropoxy group and an acetoxy group are more preferred.

In a case in which the metal-containing compound (x1) is a hydrolytic condensation product of the metal compound (I), the hydrolytic condensation product of the metal compound (I) may be a hydrolytic condensation product of the metal (I) having a hydrolyzable group with a compound including a metalloid atom, within a range not leading to impairment of the effects of the embodiments of the present invention. In other words, the hydrolytic condensation product of the metal compound (I) may also include a metalloid atom within a range not leading to impairment of the effects of the embodiments of the present invention. The metalloid atom is exemplified by a boron atom, a silicon atom and the like. The percentage content of the metalloid atom in the hydrolytic condensation product of the metal compound (I) is typically less than 50 atom % with respect to the entirety of the metal atom and the metalloid atom in the hydrolytic condensation product. The upper limit of the percentage content of the metalloid atom is preferably 30 atom % and more preferably 10 atom % with respect to the entirety of the metal atom and the metalloid atom in the hydrolytic condensation product.

The metal compound (I) is exemplified by compounds represented by the following formula (1) (hereinafter, may be also referred to as a “metal compound (I-1)”), and the like. By using the metal compound (I-1), forming a stable metal oxide is enabled, whereby a more improvement of the sensitivity of the radiation-sensitive composition (I) is enabled.

LₐMY_{b} (A)

In the above formula (A), M represents the metal atom; L represents a ligand; a is an integer of 0 to 2, wherein in a case where a is 2, a plurality of Ls may be identical or different; Y represents the hydrolyzable group selected from a halogen atom, an alkoxy group and an acyloxy group; and b is an integer of 2 to 6, wherein a plurality of Ys may be identical or different, and L is a ligand that does not fall under the definition of Y.

The metal atom represented by M is exemplified by metal atoms similar to those exemplified in connection with the metal atoms which may constitute the metal oxide included in the compound (A), and the like.

The ligand represented by L is exemplified by a monodentate ligand and a polydentate ligand.

Exemplary monodentate ligand includes a hydroxo ligand, a carboxy ligand and the like.

Exemplary polydentate ligand includes a hydroxy acid ester, a β-diketone, a β-keto ester, a β-dicarboxylic acid ester, a hydrocarbon having a π bond, a diphosphine, and the like.

Examples of the hydroxy acid ester include glycolic acid esters, lactic acid esters, 2-hydroxycyclohexane-1-carboxylic acid esters, salicylic acid esters, and the like.

Examples of the β-diketone include 2,4-pentanedione, 3-methyl-2,4-pentanedione, 3-ethyl-2,4-pentanedione, and the like.

Examples of the β-keto ester include acetoacetic acid esters, α-alkyl-substituted acetoacetic acid esters, β-ketopentanoic acid esters, benzoylacetic acid esters, 1,3-acetonedicarboxylic acid esters, and the like.

Examples of the β-dicarboxylic acid ester include malonic acid diesters, α-alkyl-substituted malonic acid diesters, α-cycloalkyl-substituted malonic acid diesters, α-aryl-substituted malonic acid diesters, and the like.

Examples of the hydrocarbon having a t bond include:

chain olefins such as ethylene and propylene;

cyclic olefins such as cyclopentene, cyclohexene and norbornene;

chain dienes such as butadiene and isoprene;

cyclic dienes such as cyclopentadiene, methylcyclopentadiene, pentamethylcyclopentadiene, cyclohexadiene and norbornadiene;

aromatic hydrocarbons such as benzene, toluene, xylene, hexamethylbenzene, naphthalene and indene; and the like.

Examples of the halogen atom which may be represented by Y include a fluorine atom, a chlorine atom, a bromine atom, an iodine atom, and the like.

Examples of the alkoxy group which may be represented by Y include a methoxy group, an ethoxy group, a propoxy group, a butoxy group, and the like.

Examples of the acyloxy group which may be represented by Y include an acetoxy group, an ethylyloxy group, a butyryloxy group, a t-butyryloxy group, a t-amylyloxy group, a n-hexanecarbonyloxy group, a n-octanecarbonyloxy group, and the like.

Y represents preferably an alkoxy group or an acyloxy group, and more preferably an isopropoxy group or an acetoxy group.

Preferably, a is 0 or 1, and more preferably 0. Preferably, b is 3 or 4, and more preferably 4. When a and b are the above-specified values respectively, it is possible to increase the percentage content of the metal oxide in the compound (A), whereby more effective promotion of the generation of the secondary electrons by the particles (A) is enabled. Consequently, a more improvement of the sensitivity of the radiation-sensitive composition (I) is enabled.

As the metal-containing compound (x1), a metal alkoxide that is neither hydrolyzed nor hydrolytically condensed, and a metal acyloxide that is neither hydrolyzed nor hydrolytically condensed are preferred.

Examples of the metal-containing compound (x1) include zirconium tetra-n-butoxide, zirconium tetra-n-propoxide, zirconium tetraisopropoxide, hafnium tetraethoxide, indium triisopropoxide, hafnium tetraisopropoxide, hafnium tetrabutoxide, tantalum pentaethoxide, tantalum pentabutoxide, tungsten pentamethoxide, tungsten pentabutoxide, tungsten hexaethoxide, tungsten hexabutoxide, iron chloride, zinc diisopropoxide, zinc acetate dihydrate, tetrabutyl orthotitanate, titanium tetra-n-butoxide, titanium tetra-n-propoxide, zirconium di-n-butoxide bis(2,4-pentanedionate), titanium tri-n-butoxide stearate, bis(cyclopentadienyl)hafnium dichloride, bis(cyclopentadienyl)tungsten dichloride, diacetato[(S)-(−)-2,2′-bis(diphenylphosphino)-1,1′-binaphthyl]ruthenium, dichloro[ethylenebis(diphenylphosphine)]cobalt, titanium butoxide oligomers, aminopropyltrimethoxytitanium, aminopropyltriethoxyzirconium, epoxycyclohexyl)ethyltrimethoxyzirconium, γ-glycidoxypropyltrimethoxyzirconium, 3-isocyanopropyltrimethoxyzirconium, 3-isocyanopropyltriethoxyzirconium, triethoxymono(acetylacetonato)titanium, tri-n-propoxymono(acetylacetonato)titanium, tri-i-propoxymono(acetylacetonato)titanium, triethoxymono(acetylacetonato)zirconium, tri-n-propoxymono(acetylacetonato)zirconium, tri-i-propoxymono(acetylacetonato)zirconium, diisopropoxybis(acetylacetonato)titanium, di-n-butoxybis(acetylacetonato)titanium, di-n-butoxybis(acetylacetonato)zirconium, tri(3-methacryloxypropyl)methoxyzirconium, tri(3-acryloxypropyl)methoxyzirconium, tin tetraisopropoxide, tin tetrabutoxide, lanthanum oxide, yttrium oxide, and the like. Of these, metal alkoxides and metal acyloxides are preferred, metal alkoxides are more preferred, and alkoxides of titanium, zirconium, hafnium, tantalum, tungsten, indium and tin are still more preferred.

The lower limit of the amount of the organic acid (y) used in the hydrolytic condensation reaction is preferably 10 parts by mass, and more preferably 30 parts by mass with respect to 100 parts by mass of the metal-containing compound (x1). Meanwhile, the upper limit of the amount of the organic acid used is preferably 1,000 parts by mass, more preferably 700 parts by mass, still more preferably 200 parts by mass, and particularly preferably 100 parts by mass with respect to 100 parts by mass of the metal-containing compound (x1). When the amount of the organic acid used falls within the above range, an appropriate adjustment of a percentage content of the organic acid (y) in the compound (A) to be obtained is enabled, whereby a more improvement of the sensitivity of the radiation-sensitive composition (I) is consequently enabled.

Upon the synthesis reaction of the compound (A), in addition to the metal compound (I) and the organic acid (y), a compound that may be the polydentate ligand represented by L in the compound of the formula (A), a compound that may be a bridging ligand, etc., may also be added. The compound that may be the bridging ligand is exemplified by a compound having hydroxy groups, isocyanate groups, ester groups or amide groups, and the like.

A procedure for carrying out the hydrolytic condensation reaction using the metal-containing compound (x1) may be exemplified by: a procedure of hydrolytically condensing the metal-containing compound (x1) in a solvent containing water; and the like. In this case, other compound having a hydrolyzable group may be added as needed. The lower limit of the amount of water used for the hydrolytic condensation reaction is preferably 0.2 times molar amount, more preferably an equimolar amount, and still more preferably 3 times molar amount with respect to the hydrolyzable group included in the metal-containing compound (x1) and the like. The upper limit of the amount of water is preferably 20 times molar amount, more preferably 15 times molar amount, and further more preferably 10 times molar amount. When the amount of water in the hydrolytic condensation reaction falls within the above range, it is possible to increase the percentage content of the metal oxide in the compound (A) to be obtained, whereby a more improvement of the sensitivity of the radiation-sensitive composition (I) is consequently enabled.

The metal-containing compound (x2) is exemplified by a metal salt compound and the like, and examples thereof include:

zinc compounds such as zinc(II) acetate and zinc(II) methacrylate;

cobalt compounds such as cobalt(II) acetate and cobalt(II) methacrylate;

nickel compounds such as nickel(II) acetate and nickel(II) methacrylate; and the like.

Alternatively, as the metal-containing compound (x2), the metal-containing compound exemplified above as the metal-containing compound (x1) may be used, and for example,

an indium compound such as indium(III) isopropoxide;

a titanium compound such as titanium(IV) isopropoxide;

a hafnium compound such as hafnium(IV) isopropoxide;

a zirconium compound such as zirconium(IV) isopropoxide; or the like may be used.

A procedure for carrying out the ligand substitution reaction using the metal-containing compound (x2) and the organic acid (y) may be exemplified by: a procedure of mixing the metal-containing compound (x2) and the organic acid (y); and the like. In this case, the mixing may be performed either in a solvent or without a solvent.

The lower limit of the amount of the organic acid (y) used in the ligand substitution reaction with respect to 100 parts by mass of the metal-containing compound (x2) is preferably 10 parts by mass, and more preferably 30 parts by mass. Meanwhile, the upper limit of the organic acid (y) used with respect to 100 parts by mass of the metal-containing compound (x2) is preferably 1,000 parts by mass, more preferably 700 parts by mass, still more preferably 300 parts by mass, and particularly preferably 150 parts by mass. When the amount of the organic acid (y) used falls within the above range, an appropriate adjustment of a percentage content of the ligand (b) in the resulting compound (A) to be obtained is enabled, whereby a more improvement of the sensitivity of the radiation-sensitive composition (I) is consequently enabled.

The lower limit of the amount of the base (z) added to a product of the hydrolytic condensation reaction or ligand substitution reaction with respect to 100 parts by mass of the of the organic acid (y) used in the reaction is preferably 10 parts by mass, more preferably 30 parts by mass, and still more preferably 50 parts by mass. Meanwhile, the upper limit of the base (z) used with respect to 100 parts by mass of the organic acid (y) used in the reaction is preferably 1,000 parts by mass, more preferably 700 parts by mass, still more preferably 300 parts by mass, and particularly preferably 150 parts by mass. When the amount of the base (z) used falls within the above range, an appropriate adjustment of a percentage content of the ligand (c) in the compound (A) to be obtained is enabled, whereby a more improvement of the sensitivity of the radiation-sensitive composition (I) is consequently enabled.

The solvent for use in the synthesis reaction of the compound (A) is not particularly limited, and solvents similar to those exemplified in connection with the solvent (B) described later may be used. Of these, alcohol solvents, ether solvents, ester solvents, and hydrocarbon solvents are preferred; alcohol solvents, ether solvents and ester solvents are more preferred; polyhydric alcohol partial ether solvents, monocarboxylic acid ester solvents and cyclic ether solvents are still more preferred; and propylene glycol monoethyl ether, ethyl acetate and tetrahydrofuran are particularly preferred.

In the case of using the organic solvent in the synthesis reaction of the compound (A), the organic solvent used may be either removed after the completion of the reaction, or directly used as the organic solvent (B) in the radiation-sensitive composition (I) without removal thereof.

The lower limit of the temperature of the synthesis reaction of the compound (A) is preferably 0° C., and more preferably 10° C. On the other hand, the upper limit of the aforementioned temperature is preferably 150° C., and more preferably 100° C.

The lower limit of the time period of the synthesis reaction of the compound (A) is preferably 1 min, more preferably 10 min, and still more preferably 1 hour. The upper limit of the time period is preferably 100 hrs, more preferably 50 hrs, and still more preferably 20 hrs.

In the case in which the compound (A) has a particulate form, the lower limit of the mean particle diameter of the compound (A) is preferably 0.5 nm, and more preferably 0.8 nm. Meanwhile, the upper limit of the mean particle diameter is preferably 20 nm, more preferably 10 nm, still more preferably 3 nm, and particularly preferably 2 nm. When the mean particle diameter of the compound (A) falls within the above range, more effective promotion of the generation of the secondary electrons by the compound (A) is enabled, whereby the sensitivity of the radiation-sensitive composition (I) can be consequently more improved. As referred to herein, the term “mean particle diameter” means a harmonic mean particle diameter on the basis of scattered light intensity, as measured by DLS (Dynamic Light Scattering).

### (B) Organic Solvent

The organic solvent (B) is not particularly limited as long as it is an organic solvent capable of dissolving or dispersing at least the compound (A) and optional component(s), etc., included as needed. The organic solvent (B) may be used either alone of one type, or in combination of two or more types thereof.

The organic solvent (B) is exemplified by an alcohol solvent, an ether solvent, a ketone solvent, an amide solvent, an ester solvent, a hydrocarbon solvent, and the like.

Examples of the alcohol solvent include:

aliphatic monohydric alcohol solvents having 1 to 18 carbon atoms such as 4-methyl-2-pentanol and n-hexanol;

alicyclic monohydric alcohol solvents having 3 to 18 carbon atoms such as cyclohexanol;

polyhydric alcohol solvents having 2 to 18 carbon atoms such as 1,2-propylene glycol;

C3-19 polyhydric alcohol partial ether solvents such as propylene glycol monomethyl ether; and the like.

Examples of the ether solvent include:

dialkyl ether solvents such as diethyl ether, dipropyl ether, dibutyl ether, dipentyl ether, diisoamyl ether, dihexyl ether and diheptyl ether;

cyclic ether solvents such as tetrahydrofuran and tetrahydropyran;

aromatic ring-containing ether solvents such as diphenyl ether and anisole;

and the like.

Examples of the ketone solvent include:

chain ketone solvents such as acetone, methyl ethyl ketone, methyl n-propyl ketone, methyl n-butyl ketone, diethyl ketone, methyl iso-butyl ketone, 2-heptanone, ethyl n-butyl ketone, methyl n-hexyl ketone, di-iso-butyl ketone and trimethylnonanone;

cyclic ketone solvents such as cyclopentanone, cyclohexanone, cycloheptanone, cyclooctanone and methylcyclohexanone;

2,4-pentanedione, acetonylacetone and acetophenone; and the like.

Examples of the amide solvent include:

cyclic amide solvents such as N,N′-dimethylimidazolidinone and N-methylpyrrolidone;

chain amide solvents such as N-methylformamide, N,N-dimethylformamide, N,N-diethylformamide, acetamide, N-methyl acetamide, N,N-dimethylacetamide and N-methylpropionamide; and the like.

Examples of the ester solvent include:

monocarboxylic acid ester solvents such as ethyl acetate, n-butyl acetate and ethyl lactate;

polyhydric alcohol carboxylate solvents such as propylene glycol acetate;

polyhydric alcohol partial ether carboxylate solvents such as propylene glycol monomethyl ether acetate;

polyhydric carboxylic acid diester solvents such as diethyl oxalate;

carbonate solvents such as dimethyl carbonate and diethyl carbonate; and the like.

Examples of the hydrocarbon solvent include:

aliphatic hydrocarbon solvents having 5 to 12 carbon atoms such as n-pentane n-hexane and decahydronaphthalene;

aromatic hydrocarbon solvents having 6 to 16 carbon atoms such as toluene and xylene; and the like.

Of these, the ester solvents and the ketone solvents are preferred, the polyhydric alcohol partial ether carboxylate solvents and the cyclic ketone solvents are more preferred, and propylene glycol monomethyl ether acetate and cyclohexanone are still more preferred.

### (C) Acid Generating Agent

The acid generating agent (C) is a component that generates an acid upon exposure to a radioactive ray. The action of the acid generated from the acid generating agent (C), enables change of solubility, etc. in the developer solution of the compound (A) in the radiation-sensitive composition (I) to be more promoted, whereby the sensitivity can be consequently more improved.

The acid generating agent (C) is exemplified by an onium salt compound, a N-sulfonyloxyimide compound, a halogen-containing compound, a diazo ketone compound, and the like.

Exemplary onium salt compound may include a sulfonium salt, a tetrahydrothiophenium salt, an iodonium salt, a phosphonium salt, a diazonium salt, a pyridinium salt, and the like.

Examples of the sulfonium salt include triphenylsulfonium trifluoromethanesulfonate, triphenylsulfonium nonafluoro-n-butanesulfonate, triphenylsulfonium perfluoro-n-octanesulfonate, triphenylsulfonium 2-bicyclo[2.2.1]hept-2-yl-1,1,2,2-tetrafluoroethanesulfonate, triphenylsulfonium camphorsulfonate, 4-cyclohexylphenyldiphenylsulfonium nonafluoro-n-butanesulfonate, 4-methanesulfonylphenyldiphenylsulfonium nonafluoro-n-butanesulfonate, triphenylsulfonium 1,1,2,2-tetrafluoro-6-(1-adamantanecarbonyloxy)-hexane-1-sulfonate, triphenylsulfonium 2-(1-adamantyl)-1,1-difluoroethanesulfonate, triphenylsulfonium 2-(adamantan-1-ylcarbonyloxy)-1,1,3,3,3-pentafluoropropane-1-sulfonate, 4-cyclohexylsulfonylphenyldiphenylsulfonium 1,2-bis(norbornanelacton-2-yloxycarbonyl)ethane-1-sulfonate, and the like.

Examples of the tetrahydrothiophenium salt include 1-(4-n-butoxynaphthalen-1-yl)tetrahydrothiophenium trifluoromethanesulfonate, 1-(4-n-butoxynaphthalen-1-yl)tetrahydrothiophenium nonafluoro-n-butanesulfonate, 1-(4-n-butoxynaphthalen-1-yl)tetrahydrothiophenium perfluoro-n-octanesulfonate, 1-(4-n-butoxynaphthalen-1-yl)tetrahydrothiophenium 2-bicyclo[2.2.1]hept-2-yl-1,1,2,2-tetrafluoroethanesulfonate, 1-(4-n-butoxynaphthalen-1-yl)tetrahydrothiophenium camphorsulfonate, 1-(6-n-butoxynaphthalen-2-yl)tetrahydrothiophenium nonafluoro-n-butanesulfonate, 1-(3,5-dimethyl-4-hydroxyphenyl)tetrahydrothiophenium nonafluoro-n-butanesulfonate, and the like.

Examples of the iodonium salt include diphenyliodonium trifluoromethanesulfonate, diphenyliodonium nonafluoro-n-butanesulfonate, diphenyliodonium perfluoro-n-octanesulfonate, diphenyliodonium 2-bicyclo[2.2.1]hept-2-yl-1,1,2,2-tetrafluoroethanesulfonate, diphenyliodonium camphorsulfonate, bis(4-t-butylphenyl)iodonium nonafluoro-n-butanesulfonate, and the like.

Examples of the N-sulfonyloxyimide compound include N-(trifluoromethylsulfonyloxy)-1,8-naphthalimide, N-(trifluoromethylsulfonyloxy)bicyclo[2.2.1]hept-5-ene-2,3-dicarboxyimide, N-(nonafluoro-n-butylsulfonyloxy)bicyclo[2.2.1]hept-5-ene-2,3-dicarboxyimide, N-(perfluoro-n-octylsulfonyloxy)-1,8-naphthalimide, N-(perfluoro-n-octylsulfonyloxy)bicyclo[2.2.1]hept-5-ene-2,3-dicarboxyimide, N-(2-bicyclo[2.2.1]hept-2-yl-1,1,2,2-tetrafluoroethylsulfonyloxy)bicyclo[2.2.1]hept-5-ene-2,3-dicarboxyimide, N-(2-(3-tetracyclo[4.4.0.1^{2.5}.1^{7.10}]dodecanyl)-1,1-difluoroethylsulfonyloxy)bicyclo[2.2.1]hept-5-ene-2,3-dicarboxyimide, N-(camphorsulfonyloxy)bicyclo[2.2.1]hept-5-ene-2,3-dicarboxyimide, and the like.

Of these, the acid generating agent (C) is preferably the onium salt compound or the N-sulfonyloxyimide compound, more preferably the sulfonium salt or the N-sulfonyloxyimide compound, still more preferably the triphenylsulfonium salt or the N-sulfonyloxyimide compound, and particularly preferably triphenylsulfonium trifluoromethanesulfonate, 4-cyclohexylsulfonylphenyldiphenylsulfonium 1,2-bis(norbornanelacton-2-yloxycarbonyl)ethane-1-sulfonate or N-(trifluoromethylsulfonyloxy)-1,8-naphthalimide.

In the case in which the radiation-sensitive composition (I) contains the acid generating agent (C), the lower limit of the content of the acid generating agent (C) with respect to the total solid content of the radiation-sensitive composition (I) is preferably 1% by mass, more preferably 4% by mass, and still more preferably 8% by mass. The upper limit of the content is preferably 40% by mass, more preferably 30% by mass, and still more preferably 20% by mass.

In the case in which the radiation-sensitive composition (I) contains the acid generating agent (C), the lower limit of the content of the acid generating agent (C) with respect to 100 parts by mass of the compound (A) is preferably 1 part by mass, more preferably 4 parts by mass, and still more preferably 8 parts by mass. The upper limit of the content of the acid generating agent (C) is preferably 40 parts by mass, more preferably 30 parts by mass, and still more preferably 25 parts by mass.

When the content of the acid generating agent (C) falls within the above range, a more improvement of the sensitivity of the radiation-sensitive composition (I) is enabled. One, or two or more types of the acid generating agent (C) may be used.

### Other Optional Component

The other optional component may be, for example, a radiation-sensitive radical generating agent, an acid diffusion control agent, a surfactant, and the like. The radiation-sensitive composition (I) may contain one type, or two or more types of the other optional component.

Radiation-Sensitive Radical Generating Agent

The radiation-sensitive radical generating agent is a component that generates a radical upon exposure to a radioactive ray. As the radiation-sensitive radical generating agent, a well-known compound may be used.

In the case in which the radiation-sensitive composition (I) contains the radiation-sensitive radical generating agent, the content of the radiation-sensitive radical generating agent may be set variously within a range not leading to impairment of the effects of the present invention.

In the case in which the radiation-sensitive composition (I) contains the radiation-sensitive radical generating agent, the upper limit of the content of the radiation-sensitive radical generating agent with respect to 100 parts by mass of the compound (A) is preferably 10 parts by mass, and more preferably 5 parts by mass. The lower limit of the content is preferably 0.1 parts by mass.

Acid Diffusion Control Agent

The acid diffusion control agent controls a phenomenon of diffusion of the acid, which was generated from the acid generating agent (C), etc. upon the exposure, in the film, whereby the effect of inhibiting unwanted chemical reactions in an unexposed region is exhibited. In addition, the storage stability and the resolution of the radiation-sensitive composition are more improved. Moreover, variation of the line width of the pattern caused by variation of post-exposure time delay from the exposure until a development treatment can be suppressed, which enables the radiation-sensitive composition with superior process stability to be obtained.

As the acid diffusion control agent, a nitrogen atom-containing compound, a photodegradable base that generates a weak acid upon an irradiation with a radioactive ray, and the like may be used.

Examples of the nitrogen atom-containing compound include:

amine compounds, for example,

monoamines e.g., monoalkylamines such as n-hexylamine, dialkylamines such as di-n-butylamine, trialkylamines such as triethylamine, aromatic amines such as aniline, etc.;

diamines such as ethylenediamine and N,N,N′,N′-tetramethylethylenediamine;

polyamines such as polyethyleneimine, polyallylamine; and

polymers of dimethylaminoethylacrylamide or the like;

amide group-containing compounds such as formamide and N-methylformamide;

urea compounds such as urea and methylurea;

nitrogen-containing heterocyclic compounds e.g., pyridine compounds such as pyridine and 2-methylpyridine, morpholine compounds such as N-propylmorpholine and N-(undecylcarbonyloxyethyl)morpholine, pyrazine, pyrazole, etc.;

nitrogen-containing heterocyclic compounds each having an acid-labile group such as N-t-butoxycarbonylpiperidine and N-t-butoxycarbonylimidazolc; and the like.

The photodegradable base is exemplified by an onium salt compound and the like that lose acid diffusion controllability through degradation upon an exposure. Exemplary onium salt compound includes a triphenylsulfonium salt, a diphenyliodonium salt, and the like.

Examples of the photodegradable base include triphenylsulfonium salicylate, triphenylsulfonium 10-camphor sulfonate, and the like.

In the case in which the radiation-sensitive composition (I) contains the acid diffusion control agent, the lower limit of the content of the acid diffusion control agent with respect to the total solid content of the radiation-sensitive composition (I) is preferably 0.1% by mass, more preferably 0.3% by mass, and still more preferably 1% by mass. The upper limit of the content of the acid diffusion control agent is preferably 20% by mass, more preferably 10% by mass, and still more preferably 5% by mass.

In the case in which the radiation-sensitive composition (I) contains the acid diffusion control agent, the lower limit of the content of the acid diffusion control agent with respect to 100 parts by mass of the compound (A) is preferably 0.1 parts by mass, more preferably 0.3 parts by mass, and still more preferably 1 part by mass. The upper limit of the content of the acid generating agent is preferably 20 parts by mass, more preferably 10 parts by mass, and still more preferably 5 parts by mass.

When the content of the acid diffusion control agent falls within the above range, a more improvement of the sensitivity of the radiation-sensitive composition (I) is enabled.

Surfactant

The surfactant exhibits the effect of improving coating properties, striation and the like. Examples of the surfactant include: nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate and polyethylene glycol distearate; and the like. Examples of a commercially available product of the surfactant include KP341 (available from Shin-Etsu Chemical Co., Ltd.), Polyflow No. 75 and Polyflow No. 95 (each available from Kyoeisha Chemical Co., Ltd.), EFTOP EF301, EFTOP EF303 and EFTOP EF352 (each available from Tochem Products Co. Ltd.), Megaface F171 and Megaface F173 (each available from DIC Corporation), Fluorad FC430 and Fluorad FC431 (each available from Sumitomo 3M Limited), ASAHI GUARD AG710, Surflon S-382, Surflon SC-101, Surflon SC-102, Surflon SC-103, Surflon SC-104, Surflon SC-105 and Surflon SC-106 (each available from Asahi Glass Co., Ltd.), and the like.

### Preparation of Radiation-Sensitive Resin Composition

The radiation-sensitive composition (I) may be prepared, for example, by mixing the compound (A) and the organic solvent (B), as well as the optional component such as the acid generating agent (C) as needed, at a certain ratio, preferably followed by filtering a mixture thus obtained through a filter having a pore size of about 0.2 μm. The lower limit of the solid content concentration of the radiation-sensitive composition (1) is preferably 0.1% by mass, more preferably 0.5% by mass, still more preferably 1% by mass, and particularly preferably 3% by mass. The upper limit of the solid content concentration is preferably 50% by mass, more preferably 30% by mass, still more preferably 15% by mass, and particularly preferably 7% by mass.

### Radiation-Sensitive Composition (II)

The radiation-sensitive composition (II) contains: a compound (hereinafter, may be also referred to as “(A′) compound” or “compound (A′)”) obtained by mixing the metal-containing compound (x), the organic acid (y) and the base (z); and the organic solvent (B). The base (z) is other than a triethylamine.

The procedure of mixing the metal-containing compound (x), the organic acid (y) and the base (z) is not particularly limited, and these three components may be blended all together. However, a preferred procedure of mixing includes: blending the metal-containing compound (x) and the organic acid (y) to allow for a ligand substitution reaction or the like; and thereafter blending the base (z) with a reaction product thus obtained.

As described in “Synthesis Procedure of Compound (A)” above for the radiation-sensitive composition (I), the metal-containing compound (x) may be obtained by, for example, a hydrolytic condensation reaction conducted using the metal-containing compound (x1), or a ligand substitution reaction conducted using the metal-containing compound (x2).

It is considered that, by blending the metal-containing compound (x), the organic acid (y) and the base (z), the organic acid (y) generates the ligand (b), and the base (z) generates the ligand (c), whereby the compound (A′) corresponding to the compound (A) of the radiation-sensitive composition (I) containing the same is generated.

In connection with the radiation-sensitive composition (II), other component included in the compound (A′), as well as the organic solvent (B), the acid generating agent (C) and the other optional component, and the preparation of the composition are similar to those for the radiation-sensitive composition (I) described above.

### Pattern-Forming Method

The pattern-forming method of another embodiment of the present invention includes: applying the radiation-sensitive composition directly or indirectly on an upper face side of a substrate (hereinafter, may be also referred to as “applying step”); exposing a film provided by the applying (hereinafter, may be also referred to as “exposure step”); and developing the film exposed (hereinafter, may be also referred to as “development step”). The radiation-sensitive composition of the embodiment of the present invention described above is employed in the pattern-forming method, and therefore the method enables a pattern superior in resolution to be formed with high sensitivity. In the following, each step is explained.

Applying Step

In this step, the radiation-sensitive composition is applied directly or indirectly on an upper face side of a substrate to form a film. Specifically, the film is formed by applying the radiation-sensitive composition such that the resulting coating film has a desired thickness, followed by prebaking (PB) to volatilize the organic solvent and the like in the coating film as needed. A procedure for applying the radiation-sensitive composition is not particularly limited, and an appropriate application procedure such as spin-coating, cast coating, roll coating, etc. may be employed. Examples of the substrate include a silicon wafer, a wafer coated with aluminum, and the like. It is to be noted that an organic or inorganic antireflective film may also be formed on the substrate in order to maximize potential of the radiation-sensitive composition.

The lower limit of an average thickness of the film to be formed in this step is preferably 1 nm, more preferably 5 nm, still more preferably 10 nm, and particularly preferably 20 nm. Meanwhile, the upper limit of the average thickness is preferably 1,000 nm, more preferably 200 nm, still more preferably 100 nm, and particularly preferably 70 nm.

The lower limit of a temperature for the PB is typically 30° C., preferably 60° C., and more preferably 80° C. The upper limit of the temperature for the PB is typically 140° C., and preferably 120° C. The lower limit of the time period of the PB is typically 5 sec, and preferably 10 sec. The upper limit of the time period of the PB is typically 24 hrs, preferably 1 hour, more preferably 600 sec, and still more preferably 300 sec.

Alternatively, the film may be formed without the PB, in other words by allowing the coating film to stand at the room temperature (e.g., 0° C. to 30° C.) for no less than 30 sec, for example, to volatilize the organic solvent and the like. Omitting the PB enables more inhibition of a damage in a wide area in the pattern formed.

In this step, in order to inhibit an influence of basic impurities, etc., in the environmental atmosphere, for example, a protective film may be provided on the film formed. Furthermore, in the case of conducting liquid immersion lithography in the exposing step as described below, in order to avoid a direct contact between a liquid immersion medium and the film, a protective film for liquid immersion may also be provided on the film formed.

Exposure Step

In this step, the film obtained by the applying step is exposed. Specifically, for example, the film is irradiated with a radioactive ray through a mask having a predetermined pattern. In this step, irradiation with a radioactive ray through a liquid immersion medium such as water, i.e., liquid immersion lithography, may be employed as needed. Examples of the radioactive ray for the exposure include: electromagnetic waves such as visible light rays, ultraviolet rays, e.g., KrF excimer laser beam (wavelength: 248 nm), far ultraviolet rays e.g. ArF excimer laser beam (wavelength: 193 nm), extreme ultraviolet rays (EUV, wavelength: 13.5 nm), X-rays and γ-rays; charged particle rays such as electron beams and α-rays; and the like. Of these, EUV and electron beams are preferred, in light of increasing the secondary electrons generated from the compound (A) having absorbed the radioactive ray.

Development Step

In this step, the film exposed is developed by using a developer solution. A predetermined pattern is thereby formed. Examples of the developer solution include an alkaline aqueous solution, an organic solvent-containing liquid, and the like. In other words, the development may be either a development with an alkali or a development with an organic solvent.

Examples of the alkaline aqueous solution include: alkaline aqueous solutions prepared by dissolving at least one alkaline compound such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo-[5.4.0]-7-undecene and 1,5-diazabicyclo-[4.3.0]-5-nonene; and the like.

The lower limit of a content of the alkaline compound in the alkaline aqueous solution is preferably 0.1% by mass, more preferably 0.5% by mass, and further more preferably 1% by mass. The upper limit of the content of the acid diffusion control agent is preferably 20% by mass, more preferably 10% by mass, and still more preferably 5% by mass.

As the alkaline aqueous solution, an aqueous TMAH solution is preferred, and a 2.38% by mass aqueous TMAH solution is more preferred.

Examples of an organic solvent in the organic solvent-containing liquid include organic solvents similar to those exemplified in connection with the organic solvent (B) in the radiation-sensitive composition, and the like. Of these, the hydrocarbon solvent is preferred, and decahydronaphthalene is more preferred.

The lower limit of a content of the organic solvent in the organic solvent-containing liquid is preferably 80% by mass, more preferably 90% by mass, further more preferably 95% by mass, and particularly preferably 99% by mass. When the content of the organic solvent falls within the above range, a further improvement of a contrast of the rate of dissolution in the developer solution between the light-exposed regions and the light-unexposed regions is enabled. Examples of components other than the organic solvent in the organic solvent-containing liquid include water, silicone oil, and the like.

An appropriate amount of a surfactant may be added to the developer solution as needed. As the surfactant, for example, an ionic or nonionic fluorochemical surfactant, a silicone surfactant, or the like may be used.

Examples of the development procedure include: a dipping procedure in which the substrate is immersed for a given time period in the developer solution charged in a container; a puddle procedure in which the developer solution is placed to form a dome-shaped bead by way of the surface tension on the surface of the substrate for a given time period to conduct a development; a spraying procedure in which the developer solution is sprayed onto the surface of the substrate; a dynamic dispensing procedure in which the developer solution is continuously applied onto the substrate that is rotated at a constant speed while scanning with a developer solution-application nozzle at a constant speed; and the like.

It is preferred that, following the development, the substrate is rinsed by using a rinse agent such as water, alcohol, etc., and then dried. A procedure for the rinsing is exemplified by a procedure of continuously applying the rinse agent onto the substrate that is rotated at a constant speed (spin-coating procedure), a procedure of immersing the substrate for a given time period in the rinse agent charged in a container (dipping procedure), a procedure of spraying the rinse agent onto the surface of the substrate (spraying procedure), and the like.

### EXAMPLES

Hereinafter, the present invention is explained in detail by way of Examples, but the present invention is not limited to these Examples.

### Synthesis of Compound (A)

The compounds (A) were synthesized according to the following procedure. The metal-containing compound (x), the organic acid (y) and the base (z) which were used in the syntheses of the compounds (A) are shown below.

(x) Metal-Containing Compound

X-1: zinc(II) acetate dihydrate (Zn(OAc)₂.2H₂O)

X-2: zinc(II) methacrylate (Zn(CH₂═C(CH₃)CO₂)₂)

X-3: cobalt(II) acetate tetrahydrate (Co(OAc)₂.4H₂O)

X-4: nickel(II) acetate tetrahydrate (Ni(OAc)₂.4H₂O)

X-5: indium(III) isopropoxide (In(Oi-Pr)₃)

X-6: hafnium(IV) isopropoxide (Hf(Oi-Pr)₄)

X-7: zirconium(IV) isopropoxide (Zr(Oi-Pr)₄)

(y) Organic Acid

Y-1: m-toluic acid

Y-2: 3-fluorobenzoic acid

Y-3: 3-iodobenzoic acid

(z) Base

Z-1: triethylamine

Z-2: diisopropylethylamine

Z-3: tri-n-octylamine

Z-4: N-methylpyrrolidine

Z-5: pyrrolidine

Z-6: di-n-butylamine

Z-7: n-octylamine

Z-8: aniline

### Synthesis Example 1

In 40.0 g of ethyl acetate, 1.7 g of the compound (X-1) and 1.9 g of the compound (Y-1) were dissolved. To this solution, 2.2 g of the compound (Z-1) was added dropwise and the mixture was heated at 65° C. for 10 hrs. Distilling away ethyl acetate by vacuum concentration gave a compound (A-1) having a particulate form that includes a metal atom and a ligand derived from an organic acid. This compound (A-1) had a mean particle diameter of 1.6 nm as determined by DLS.

### Synthesis Examples 2 to 17

Compounds (A-2) to (A-17) were each synthesized by a similar operation to that of Synthesis Example 1 except that each component of the type and in the amount blended shown in Table 1 below was used. The mean particle diameter of each of the compounds as determined by DLS is shown together in Table 1.

TABLE 1

| | | (x) Metal- | | | | | | |
|---|---|---|---|---|---|---|---|---|
| | | containing | | | | | | |
| | | compound | | (y) Organic acid | | (z) Base | | Mean |
| | | | amount | | amount | | amount | particle |
| | (A) | | blended | | blended | | blended | diameter |
| | Compound | type | (g) | Type | (g) | Type | (g) | (nm) |
| Synthesis | A-1 | X-1 | 1.7 | Y-1 | 1.9 | Z-1 | 2.2 | 1.6 |
| Example 1 | | | | | | | | |
| Synthesis | A-2 | X-1 | 1.7 | Y-1 | 1.9 | Z-2 | 2.7 | 1.7 |
| Example 2 | | | | | | | | |
| Synthesis | A-3 | X-1 | 1.7 | Y-1 | 1.9 | Z-3 | 6.8 | 2.0 |
| Example 3 | | | | | | | | |
| Synthesis | A-4 | X-1 | 1.7 | Y-1 | 1.9 | Z-4 | 1.7 | 1.6 |
| Example 4 | | | | | | | | |
| Synthesis | A-5 | X-1 | 1.7 | Y-1 | 1.9 | Z-5 | 1.3 | 1.6 |
| Example 5 | | | | | | | | |
| Synthesis | A-6 | X-1 | 1.7 | Y-1 | 1.9 | Z-6 | 2.7 | 1.7 |
| Example 6 | | | | | | | | |
| Synthesis | A-7 | X-1 | 1.7 | Y-1 | 1.9 | Z-7 | 2.6 | 1.8 |
| Example 7 | | | | | | | | |
| Synthesis | A-8 | X-1 | 1.7 | Y-1 | 1.9 | Z-8 | 1.5 | 1.7 |
| Example 8 | | | | | | | | |
| Synthesis | A-9 | X-2 | 2.0 | Y-1 | 1.9 | Z-7 | 2.6 | 1.8 |
| Example 9 | | | | | | | | |
| Synthesis | A-10 | X-2 | 2.0 | Y-1 | 1.9 | Z-8 | 1.5 | 1.7 |
| Example 10 | | | | | | | | |
| Synthesis | A-11 | X-1 | 1.7 | Y-2 | 2.0 | Z-7 | 2.6 | 1.8 |
| Example 11 | | | | | | | | |
| Synthesis | A-12 | X-1 | 1.7 | Y-3 | 3.5 | Z-7 | 2.6 | 2.0 |
| Example 12 | | | | | | | | |
| Synthesis | A-13 | X-3 | 1.9 | Y-1 | 1.9 | Z-7 | 2.6 | 1.8 |
| Example 13 | | | | | | | | |
| Synthesis | A-14 | X-4 | 1.9 | Y-1 | 1.9 | Z-7 | 2.6 | 1.8 |
| Example 14 | | | | | | | | |
| Synthesis | A-15 | X-5 | 2.3 | Y-1 | 1.9 | Z-7 | 2.6 | 1.8 |
| Example 15 | | | | | | | | |
| Synthesis | A-16 | X-6 | 3.2 | Y-1 | 1.9 | Z-7 | 2.6 | 1.8 |
| Example 16 | | | | | | | | |
| Synthesis | A-17 | X-7 | 2.5 | Y-1 | 1.9 | Z-7 | 2.6 | 1.7 |
| Example 17 | | | | | | | | |

### Preparation of Radiation-Sensitive Composition

The organic solvents (B) and the acid generating agents (C) used for preparing the radiation-sensitive compositions are shown below.

(B) Organic Solvent

B-1: propylene glycol monomethyl ether acetate (compound represented by the following formula (B-1))

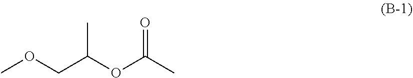

(C) Acid Generating Agent

C-1: N-(trifluoromethylsulfonyloxy)-1,8-naphthalimide (compound represented by the following formula (C-1))

C-2: triphenylsulfonium trifluoromethanesulfonate (compound represented by the following formula (C-2))

C-3: 4-cyclohexylsulfonylphenyldiphenylsulfonium 1,2-di(norbornanelacton-2-yloxycarbonyl)ethane-1-sulfonate (compound represented by the following formula (C-3))

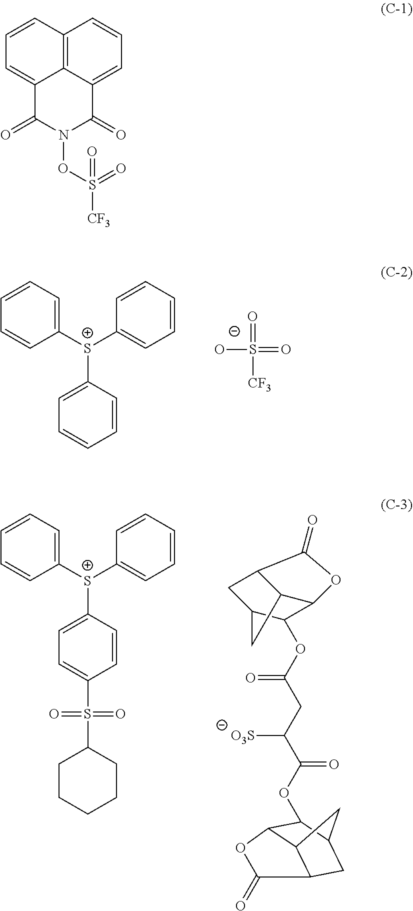

### Comparative Example 1

A mixed liquid having a solid content concentration of 5% by mass was provided by mixing 100 parts by mass of (A-1) as the compound (A), and 10 parts by mass of (B-1) as the organic solvent (B) and (C-1) as the acid generating agent (C). The mixed liquid was filtered through a membrane filter having a pore size of 0.20 μm to prepare a radiation-sensitive composition (R-1).

### Examples 1 to 19

Radiation-sensitive compositions (R-2) to (R-20) were each prepared by a similar operation to that of Comparative Example 1 except that each component of the type and in the amount blended shown in Table 2 below was used.

TABLE 2

| | | (A) Compound | | | (C) Acid generating agent | |
|---|---|---|---|---|---|---|
| | Radiation- | | amount | | | amount |
| | sensitive | | blended | (B) Organic | | blended |
| | composition | Type | (parts by mass) | solvent | type | (parts by mass) |
| Comparative | R-1 | A-1 | 100 | B-1 | C-1 | 10 |
| Example 1 | | | | | | |
| Example 1 | R-2 | A-2 | 100 | B-1 | C-1 | 10 |
| Example 2 | R-3 | A-3 | 100 | B-1 | C-1 | 10 |
| Example 3 | R-4 | A-4 | 100 | B-1 | C-1 | 10 |
| Example 4 | R-5 | A-5 | 100 | B-1 | C-1 | 10 |
| Example 5 | R-6 | A-6 | 100 | B-1 | C-1 | 10 |
| Example 6 | R-7 | A-7 | 100 | B-1 | C-1 | 10 |
| Example 7 | R-8 | A-8 | 100 | B-1 | C-1 | 10 |
| Example 8 | R-9 | A-9 | 100 | B-1 | C-1 | 10 |
| Example 9 | R-10 | A-10 | 100 | B-1 | C-1 | 10 |
| Example 10 | R-11 | A-11 | 100 | B-1 | C-1 | 10 |
| Example 11 | R-12 | A-12 | 100 | B-1 | C-1 | 10 |
| Example 12 | R-13 | A-13 | 100 | B-1 | C-1 | 10 |
| Example 13 | R-14 | A-14 | 100 | B-1 | C-1 | 10 |
| Example 14 | R-15 | A-15 | 100 | B-1 | C-1 | 10 |
| Example 15 | R-16 | A-16 | 100 | B-1 | C-1 | 10 |
| Example 16 | R-17 | A-17 | 100 | B-1 | C-1 | 10 |
| Example 17 | R-18 | A-7 | 100 | B-1 | C-1 | 20 |
| Example 18 | R-19 | A-7 | 100 | B-1 | C-2 | 10 |
| Example 19 | R-20 | A-7 | 100 | B-1 | C-3 | 10 |

### Pattern Formation

### Comparative Example 1

The radiation-sensitive composition (R-1) prepared by Comparative Example 1 described above was spin-coated onto a silicon wafer by a simplified spin-coater to form a film having an average thickness of 50 nm. Subsequently, the film was exposed to an electron beam by using an electron beam writer (“JBX-9500FS” available from JEOL, Ltd.) to permit patterning. After completion of the exposure to the electron beam, the film was developed with decahydronaphthalene and then dried to form a negative-tone pattern.

### Examples 1 to 19

Pattern formation with each radiation-sensitive composition was performed in a similar manner to Comparative Example 1 except that each radiation-sensitive composition shown in Table 3 below was used.

### Evaluations

The radiation-sensitive compositions prepared as described above were evaluated in terms of the sensitivity and the resolution, according to the following procedure. The results of the evaluations are shown together in Table 3.

Sensitivity

An exposure dose at which a line-and-space pattern (1L 1S) was formed with a line width of 1:1 configured with line parts and space parts formed by neighboring line parts, each part having a width of 100 nm was defined as an “optimum exposure dose”, and the optimum exposure dose was defined as “sensitivity” (μC/cm²). The smaller value indicates superior sensitivity.

Resolution

Line-and-space patterns (1L 1S) were formed to have various line widths, and a half-pitch of the pattern in which a total of the line widths and the space widths was the smallest among the line-and-space patterns having the line width of 1:1 being maintained was defined as a limiting resolution (nm), which was employed as an indicator of the resolution. The smaller value indicates superior limiting resolution.

TABLE 3

| | Radiation- | | |
|---|---|---|---|
| | sensitive | Resolution | Sensitivity |
| | composition | (nm) | (μC/cm²) |
| Comparative | R-1 | 45 | 65 |
| Example 1 | | | |
| Example 1 | R-2 | 50 | 30 |
| Example 2 | R-3 | 50 | 25 |
| Example 3 | R-4 | 50 | 40 |
| Example 4 | R-5 | 40 | 45 |
| Example 5 | R-6 | 40 | 40 |
| Example 6 | R-7 | 45 | 45 |
| Example 7 | R-8 | 55 | 45 |
| Example 8 | R-9 | 55 | 35 |
| Example 9 | R-10 | 60 | 35 |
| Example 10 | R-11 | 45 | 40 |
| Example 11 | R-12 | 45 | 40 |
| Example 12 | R-13 | 50 | 35 |
| Example 13 | R-14 | 50 | 35 |
| Example 14 | R-15 | 50 | 40 |
| Example 15 | R-16 | 50 | 40 |
| Example 16 | R-17 | 50 | 45 |
| Example 17 | R-18 | 40 | 40 |
| Example 18 | R-19 | 40 | 50 |
| Example 19 | R-20 | 40 | 40 |

From the results shown in Table 3, the radiation-sensitive compositions and the pattern-forming methods of Examples were revealed to enable a pattern to be formed with superior sensitivity and favorable resolution maintained. In general, an electron beam exposure is known to exhibit a similar tendency to the case of an EUV exposure, and therefore, the radiation-sensitive compositions of Examples are expected to enable a pattern to be formed with superior sensitivity and favorable resolution maintained, also in the case of the EUV exposure.

The radiation-sensitive composition and the pattern-forming method according to the embodiments of the present invention enable a pattern to be formed with superior sensitivity and favorable resolution maintained. Therefore, these can be suitably used in formation of a fine resist pattern in a lithography process of various types of electronic devices such as a semiconductor device and a liquid crystal device, in which further progress of miniaturization is expected.

Obviously, numerous modifications and variations of the present invention are possible in light of the above teachings. It is therefore to be understood that within the scope of the appended claims, the invention may be practiced otherwise than as specifically described herein.

What is claimed is:

1. A radiation-sensitive composition comprising:
a compound comprising a metal atom, a ligand derived from an organic acid, and a ligand derived from a base; and
an organic solvent,
wherein the base is other than a triethylamine.

2. The radiation-sensitive composition according to claim 1, further comprising a radiation-sensitive acid generating agent.

3. The radiation-sensitive composition according to claim 1, wherein the base has at least one of: a pKb of no less than 3.1; a boiling point of no less than 95° C.; and a molecular weight of no less than 105.

4. The radiation-sensitive composition according to claim 1, wherein the organic acid has a boiling point of no greater than 400° C.

5. A pattern-forming method comprising:
applying the radiation-sensitive composition according to claim 1 directly or indirectly on an upper face side of a substrate to provide a film;
exposing the film provided by the applying of the radiation-sensitive composition; and
developing the film exposed.

6. A radiation-sensitive composition comprising:
a compound obtained by blending a metal-containing compound, an organic acid and a base; and
an organic solvent,
wherein the base is other than a triethylamine.

7. The radiation-sensitive composition according to claim 6, further comprising a radiation-sensitive acid generating agent.

8. The radiation-sensitive composition according to claim 6, wherein the base has at least one of: a pKb of no less than 3.1; a boiling point of no less than 95° C.; and a molecular weight of no less than 105.

9. The radiation-sensitive composition according to claim 6, wherein the organic acid has a boiling point of no greater than 400° C.

10. A pattern-forming method comprising:
applying the radiation-sensitive composition according to claim 6 directly or indirectly on an upper face side of a substrate to provide a film;
exposing the film provided by the applying of the radiation-sensitive composition; and
developing the film exposed.
